(19) United States
(12) Patent Application Publication
(10) Pub. No.: US 2022/0208579 A1
(43) Pub. Date: Jun. 30, 2022

(54) SYNCHRONOUS SUBSTRATE TRANSPORT AND ELECTRICAL PROBING

(71) Applicant: Photon Dynamics, Inc., San Jose, CA (US)

(72) Inventors: Neil Dang Nguyen, Milpitas, CA (US); Kent Nguyen, San Jose, CA (US); Kiran Jitendra, San Jose, CA (US); Inho Chae, San Jose, CA (US); Gordon Yue, Sunnyvale, CA (US)

(21) Appl. No.: 17/136,314

(22) Filed: Dec. 29, 2020

(51) Int. Cl. H01L 21/67; H01L 21/677; G01N 21/88; G01R 31/26

(52) U.S. Cl. CPC H01L 21/67288; G01R 31/2601; G01N 21/8851; H01L 21/67784

(57) ABSTRACT

A system for glass substrate inspection, such as flat patterned media, includes an air table that holds the glass substrate. The air table includes chucklets that emit gas as air bearings. A camera is disposed over the air table and moves in a direction across a width of a top surface of the glass substrate. An assembly includes a gripper and a probe bar configured to be transported under the camera. The gripper is configured to grip a bottom surface of the glass substrate opposite the top surface. The probe bar delivers driving signals to the glass substrate through a plurality of probe pins.

### FIELD OF THE DISCLOSURE

This disclosure relates to inspection systems for flat patterned media.

### BACKGROUND OF THE DISCLOSURE

Flat patterned media can be inspected using optical techniques. For example, automated optical inspection (AOI) can be performed on large flat patterned media, such as thin film transistor (TFT) arrays. TFT arrays are the main component of liquid crystal displays (LCD). During the manufacturing of LCD panels, large clear sheets of thin glass are used as a substrate for the deposition of various layers of materials to form electronic circuits that are intended to function as a plurality of separable, identical display panels. This deposition is usually done in stages, where in each stage, a particular material (such as metal, indium tin oxide (ITO), silicon, amorphous silicon, etc.) is deposited over a previous layer or upon the bare glass substrate in adherence to a predetermined pattern. Each stage includes various steps such as deposition, masking, etching, and stripping.

Production defects can occur during each of these stages and at various steps within a stage. Production defects can have electronic and/or visual implications for the performance of the final LCD product. Such defects include, but are not limited to, circuit shorts, opens, foreign particles, miss-deposition, feature size problems, over-etching, and under-etching. For TFT LCD panel or other flat patterned media inspection, the defects subject to detection are small (e.g., down to individual micrometers), thus requiring demanding defect detection limits.

Mere detection of defects may be insufficient. Detected defects must also be classified as process defects (i.e., minor imperfections), which do not undermine the performance of the finished product, but are an early indication of the array manufacturing process drifting out of optimum conditions; reparable defects that can be repaired to improve the array production yield; and killer defects, which disqualify the TFT array from further use.

In a conventional AOI system, there is a compromise between a number of critical characteristics, such as the optical scanning resolution, TACT time, detection limits, and cost. These characteristics determine the usefulness or type of application of the AOI instrument. Typically, one characteristic can be optimized or improved by compromising another. For example, the AOI system resolution can be increased, resulting in improved detection limits and making smaller defects detectable. These improvements would, however, have an adverse effect on the time needed to complete the inspection (TACT time) or the system cost. Conversely, for a different type of application, the detection limits can be relaxed making larger defects detectable by lowering the system resolution, therefore achieving a shorter TACT time and reduced system cost.

TACT time is generally defined as time it take to load a glass panel which includes at least one individual substrate containing features on an LCD panel under inspection. The glass panel is loaded, moved, and aligned. The inspection head locates the first site for inspection. The payload in the inspection head is moved in the X axis and scans across the glass panel. Upon the completion, the glass panel is moved to the next row. TACT is the time in take to complete one glass panel.

Current AOI systems cannot provide high detection sensitivity and TACT time matched to the production speed at an acceptable price. This has imposed on the LCD industry the use of low performance, short TACT time systems as in-line instruments. Higher detection sensitivity systems requiring longer inspection times incompatible with the production speed could only be used as off-line instruments, capable of inspecting only selected TFT panels. This method of inspection is often referred to as the sampling mode of operation.

The operating resolution of an AOI system has a direct impact on its cost. For a short TACT time, this cost increases almost exponentially with the increase in operating resolution. Therefore, for high-throughput, in-line applications at production speeds, where a short TACT time is required, only comparatively lower resolutions have been feasible for the system.

Therefore, improved systems and methods of inspection are needed for flat patterned media.

### BRIEF SUMMARY OF THE DISCLOSURE

A system is provided in a first embodiment. The system comprises an air table configured to hold a glass substrate. The air table includes an array of rail chucklets. Each of the rail chucklets has apertures configured to emit gas as air bearings. A camera is disposed over the air table. The camera is configured to move in a direction across a width of a top surface of the glass substrate that is imaged using the camera. An assembly includes a gripper and a probe bar configured to be transported under the camera. The gripper is configured to grip a bottom surface of the glass substrate opposite the top surface. The probe bar delivers driving signals to the glass substrate through a plurality of probe pins. At least one actuator configured to transport the assembly under the camera.

The probe bar can extend across the air table.

The gripper can grip the glass substrate using a vacuum force.

The gripper can extend across a width of the glass substrate.

The system can include displacement sensors disposed on the assembly.

A method is provided in a second embodiment. The method comprises attaching a probe bar to a bottom surface of a glass substrate. The glass substrate is transported under a camera using an air table with the probe bar. The air table includes an array of rail chucklets. Each of the rail chucklets has apertures configured to emit gas as air bearings. Driving signals are delivered to the glass substrate using the probe bar through a plurality of probe pins during the transporting of the glass substrate. The camera moves across a width of a top surface of the glass substrate. The top surface is opposite the bottom surface.

The method can include inspecting the glass substrate with a camera disposed a distance from the top surface of the glass substrate during the transporting of the glass substrate.

The probe pins can be disengaged from the glass substrate after the inspecting is complete for an entirety of the glass substrate.

The method can include removing the probe bar from the bottom surface of the glass surface after the inspecting is complete for an entirety of the glass substrate.

The probe pins can be disengaged from the glass substrate after the inspecting is complete for a row of panels on the glass substrate.

The method can include removing the probe bar from the bottom surface of the glass surface after the inspecting is complete for a row of panels on the glass substrate.

The method can include classifying defects in the glass substrate using the data from the camera.

The method can include vacuum gripping the bottom surface of the glass substrate using an assembly with the probe bar during the transporting and the delivery of the driving signals. The vacuum gripping can be disengaged after inspection is complete for an entirety of the glass substrate or after inspection is complete for a row of panels on the glass substrate.

### DESCRIPTION OF THE DRAWINGS

For a fuller understanding of the nature and objects of the disclosure, reference should be made to the following detailed description taken in conjunction with the accompanying drawings, in which:

FIG. 1 is a view of an embodiment of a system in accordance with the present disclosure;

FIG. 2 is a view of an integrated electrical probe with a probe bar;

FIG. 3 is a front view of the integrated electrical probe of FIG. 2;

FIG. 4 illustrates a preloaded chuck with an embedded displacement sensor; and

FIG. 5 is an embodiment of a flowchart of a method in accordance with the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments of the present disclosure enable array checker (AC) testing on flexible or rigid substrates, such as glass substrates or other flat patterned media. The AC system can probe and activate the panels (e.g., LCD panels) for the modulator to perform inspection through the optical camera. Combining substrate probing and transportation results in better TACT time and lower costs in a split axes system. Embodiments disclosed herein enable the probes to be in contact with substrate until electrical inspection of a device under test (DUT) is complete. This can eliminate the frequency of contact test to be performed to confirm a probe-to-probe pad contact. The use of a preload chuck can eliminate the need to vacuum-grip the substrate during inspection and release the substrate during transport. This results in better throughput along with reduced costs because of relaxed flatness compliance on the chuck.

In these embodiments, the glass substrate DUT is the entire sheet of glass which contain features of the LCD/OLED such as a TV, monitor, tablet, cellphone, or other device. The number of panel under test depends on a configuration for the features.

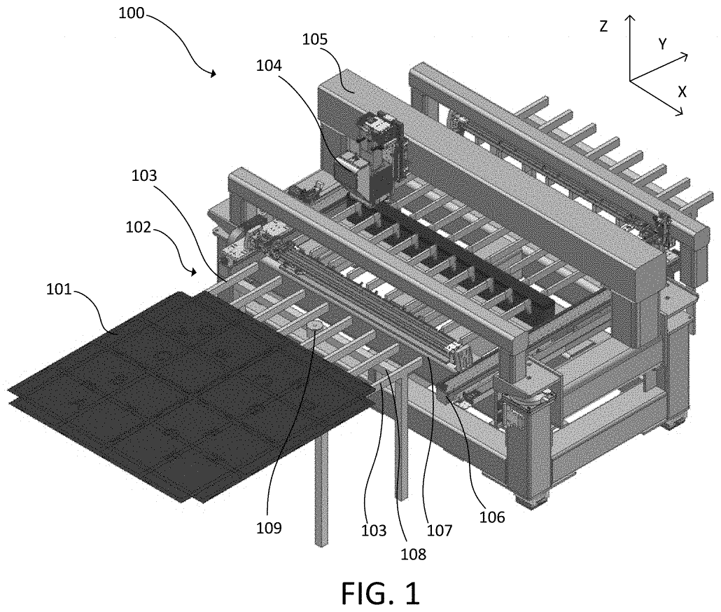

FIG. 1 is a view of an embodiment of a system 100. An air table 102 is configured to hold a glass substrate 101 or other substrates. The air table 102 includes an array of rail chucklets 103. Each of the rail chucklets 103 has apertures configured to emit gas as air bearings. This can levitate the glass substrate 101 above the rail chucklets 103. Eight chucklets 103 are illustrated in FIG. 1 supporting the glass substrate 101, but more or fewer chucklets 103 are possible.

The chucklets 103 can be arranged in an array of parallel rails. The chucklets 103 can be hollow and may be precisely aligned to support a flat large thin sheet of glass, such as glass substrate 101. The chucklets 103 can rest on cross braces, such as the cross brace 108. Vacuum clamp 109 can be mounted on a rotation and alignment slide. Edge sensors (not shown) are used to detect the edge of a glass substrate 101. The chucklets 103 employ air bearings (such as apertures in the face opposite the underside of the glass substrate 101) and are coupled at one end into a transverse vacuum plenum, thereby forming a grill for supporting the glass substrate 101 to be tested. The chucklets 103 can be in fluid communication with a gas source and/or pump.

This arrangement employs air bearings in the chucklets 103 in combination with vacuum clamp 109 and associated rotation and alignment slide to accurately control and stabilize the vertical location of the glass substrate 101 while the glass substrate 101 is positioned beneath the camera 104.

A camera 104 is disposed over the air table 102. The camera 104 (or other payload) is configured to move in a direction across a width of a top surface of the glass substrate 101. For example, the camera 104 can move in the X direction. The camera 104 may be mounted on the fixed beam 105, which extends over the air table 102. Using actuators (not illustrated) the camera 104 can move in the X direction, Y direction, and/or Z direction relative to the fixed beam 105. Images and information can be used for inspection of the glass substrate 101 and/or classification of defects on the glass substrate 101. This may be performed by a processor in electronic communication with the camera 104.

A substrate handler 106 is can be used to transport the glass substrate 101 under the camera 104 on the air table 102. The probe bar 107 can move using the substrate handler 106. For example, actuators can move the probe bar 107 along the substrate handler 106. The substrate handler 106 can include a rail or other track for the probe bar 107. The substrate handler 106 also can include grippers for a side surface of the glass substrate 101 (i.e., between the top and bottom surfaces) or gas jet to help steer the glass substrate 101.

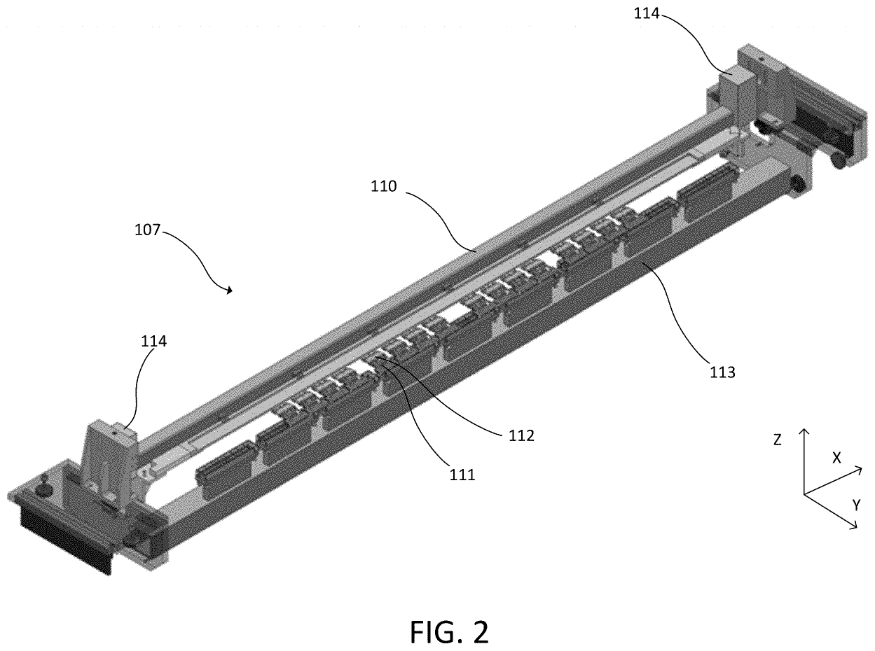

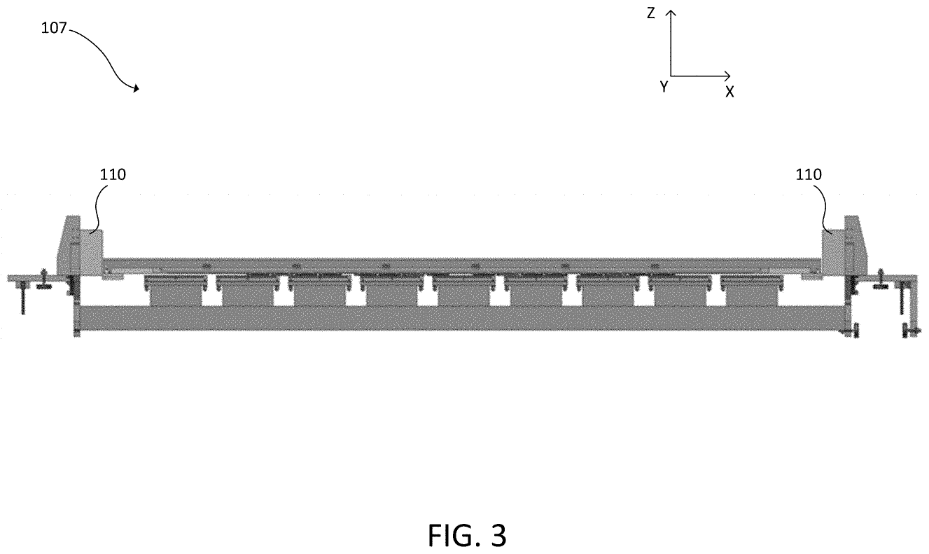

The probe bar 107 can include a gripper 110, which are shown in FIGS. 2 and 3. The gripper 110 can contact the edges and/or bottom of the glass substrate 101 as the glass substrate 101 is transported under the camera 104. Each gripper 110 is applied by vacuum on surface of the glass substrate 101. Each gripper 110 can include one or more apertures to apply suction or vacuum to the surface of the glass substrate 101. The gripper 110 can be in fluid communication with a vacuum pump. While only one gripper 110 is shown, two or more separate grippers 110 can be part of the assembly with the probe bar 107.

Probing and gripping of the glass substrate 101 can occur simultaneously. Both the gripper 110 and probes of the probe bar 107 are on the motion axis. The gripping of the glass can allow the entire DUT to move without repeatedly gripping and un-gripping, which reduces overall TACT time.

Turning back to FIG. 1, a probe bar 107 is disposed over the air table 102 and can be integrated with glass substrate 101 motion using the system 100. The probe bar 107 is configured to grip a bottom surface of the glass substrate 101, such as with the gripper 110. The bottom surface may be opposite the top surface, which faces the camera 104, in the Z direction. Thus, the bottom surface of the glass substrate 101 may be exposed to the air table 102. The probe bar 107 can be transported under the camera 104 with the glass substrate 101. The probe bar 107 can extend across the air table in the X direction. A width of the probe bar 107 in the X direction may be similar to a width of the glass substrate 101 in the X direction.

The probe bar 107 can be used to deliver driving signals to devices undergoing electrical test. For example, the glass substrate 101 may be an LCD or OLED display panel defined on a glass or polymer substrate. Previous designs of the probing assembly involved probes mounted on a dedicated axis providing vertical and/or horizontal motion to enable contact between the probes and the probe pads on the DUT. These designs require the probes to not be in contact with the DUT during substrate or probe motion.

Embodiments of the present disclosure enable probing during glass substrate 101 motion. This is made possible by combining the probing and substrate handling into a single assembly as shown in FIGS. 2 and 3. Motion of the glass substrate 101 can be provided by a single probe bar 107 or multiple flat bars on a linear axis gripping the glass substrate 101 during motion.

The flat bars also serve as the support structure for the probes during contact with DUT, preventing the glass substrate 101 from sagging. The force of the spring loaded probe pin activated by actuator and force applied during the clamping force can cause sagging in the glass substrate 101. The chucklets 103 can support the bottom of the glass substrate 101.

The probe bar 107 includes one or more probe blocks 111. Each probe block 111 includes a probe pin 112. The probe pin 112 can contact the glass substrate 101. The probe blocks 111 are disposed on a support 113. The support 113, probe blocks 111, and gripper 110 are configured to be transported together by an actuator in a single assembly.

The probe bar 107 can include or be connected with one or more actuators 114. The actuators 114 can compress the probe blocks 111 and probe pins 112 against a glass substrate. Thus, the actuators 114 can enable motion in the Z-direction. The actuators 114 or other actuators can move the probe bar in the Y direction.

The gripper 110 can extend across a width of the glass substrate 101. Vacuum can be provided to the gripper 110 using a vacuum pump (not shown) and tubing. The gripper 110 can be used to hold the glass substrate 101 while the probe bar moves the glass substrate 101 over the rail chucklets 103.

The probe bar unit can move in one direction (e.g., forward in the Y direction) during the inspection of a given panel row, but can move in the opposite direction when switching to next row of panels or next glass substrate 101. In case of multiple probe bar units, one unit can be used to probe the leading side of the panel and another used to probe the trailing side. This panel row to panel row motion is sequential, so that one unit holds the glass substrate 101 while the other one moves.

In an instance, the probe bar units can be used to “stretch” a thin, flexible substrate to prevent it from sagging. This can ensure a more uniform working distance during testing with the AC.

Use of the probe bar 107 offers TACT time and reliability benefits because the probes do not need to be released from the DUT during motion. Furthermore, the flat bar support provides, in addition to improved uniformity, reduced variation in probing force during the full inspection of the DUT. Moreover, the probe bar 107 enables costs saving by reducing the number of axes required by two because the front and back substrate handler and probe bar axes are combined

Electrical inspection of a flat panel display using a voltage imaging optical subsystem (VIOS) may require the DUT to be flat or parallel with the sensor surface. Previous designs involved securing the flat panel display substrate on a flat surface by means of a vacuum during the inspection process. The system 100 reduces the need for glass substrate 101 to be secured on a flat surface by introducing a vacuum preload method to obtain a flat DUT without requiring contact. The system 100 can provide better throughput because the glass substrate 101 may not be secured and released for every unit inspection of DUT. This opens up possibilities for roll-to-roll inspection and other process related application.

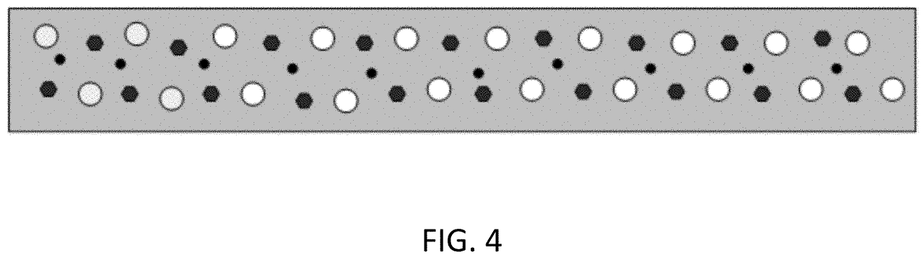

Furthermore, the system 100 can monitor a local vertical displacement of the bottom surface of the DUT in real time using multiple displacement sensors as shown in FIG. 4. The sensors are represented in FIG. 4 by the hexagons and different-sized circles and can be part of the assembly with the probe bar 107. Acquisition of CAL frames (i.e., a calibration image is taken and used as the standard) on every site can be skipped, which can promote faster TACT time. Instead of measuring CAL frames on every site, a quasi-static calibration can correct for the non-uniformity in the VIOS. The modulator, illuminator, optics, sensor tend not to change from site to site. A real-time model-based correction of the measured values can be based on the measured glass fly height values. This can be accomplished by measuring the image intensity as a function of gap offline and building a reliable model for this data. The correction required for each sensor pixel can be obtained by a bi-linear interpolation of the gap values from each sensor pixel from the measured glass flatness values. Embodiments of the system 100 may be particularly appealing for scanning-based applications (e.g., VIOS or electrostatic sensing), where the real-time measurement of CAL images is simply not possible because the sensor is constantly in motion.

In an instance, a linear variable displacement transducer (LVTD) sensor can be used to measure displacement of the glass substrate.

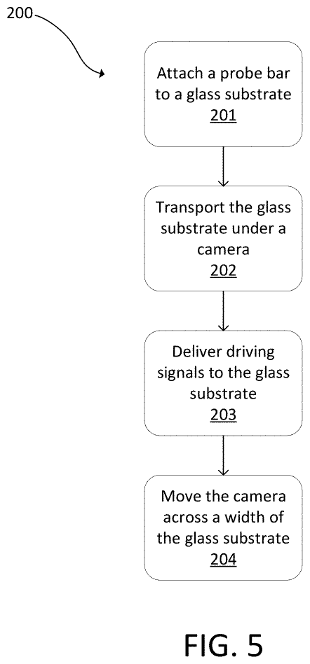

FIG. 5 is an embodiment of a flowchart of a method 200. The method 200 includes attaching a probe bar, such as that in FIGS. 1-3, to a bottom surface of a glass substrate at 201. The glass substrate can be transported under a camera at 202 using an air table with the probe bar. The air table includes an array of rail chucklets. Each of the rail chucklets has apertures that can be configured to emit gas as air bearings. Driving signals are delivered to the glass substrate using the probe bar during the transporting at 203. The signals can be delivered while the glass substrate is in motion or while it is temporarily at rest under the camera. At 204, the camera is moved across a width of a top surface of the glass substrate. The top surface of the glass substrate is opposite the bottom surface.

The camera can be used to inspect the glass substrate. The camera can be disposed a distance from the top surface of the glass substrate during the transportation of the glass substrate.

The probe bar can move without gripper release during the probing cycle until the entire row of display is inspected. Thus, the system can provide a continuous inspection cycle without lifting probes with each glass move. The gripper can contact the glass substrate and the probe pins can remain in contact with the glass substrate during transport. The gripper and the probe pins can release or disengage after inspection of part or the entire glass substrate is complete.

The air table can float the glass substrate 101 under the camera 104. The air table may be deactivated during when the glass substrate 101 is positioned under the camera 104 and/or during imaging by the camera 104. The gripper 110 and probe pins 112 may remaining attached during imaging by the camera 104. After imaging by the camera 104, the air table may be reactivated to reposition the glass substrate 101. For example, the glass substrate 101 may be moved so that a new row in the glass substrate 101 is positioned under the camera 104.

While embodiments of this disclosure are applicable to inspection of any flat, periodically patterned media, the embodiments can be particularly useful for the high throughput, in-line inspection of TFT arrays at various stages of their production.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
an air table configured to hold a glass substrate, wherein the air table includes an array of rail chucklets, each of the rail chucklets having apertures configured to emit gas as air bearings;
a camera disposed over the air table, wherein the camera is configured to move in a direction across a width of a top surface of the glass substrate that is imaged using the camera;
an assembly that includes a gripper and a probe bar configured to be transported under the camera, wherein the gripper is configured to grip a bottom surface of the glass substrate opposite the top surface, and wherein the probe bar delivers driving signals to the glass substrate through a plurality of probe pins; and
at least one actuator configured to transport the assembly under the camera.

2. The system of claim 1, wherein the probe bar extends across the air table.

3. The system of claim 1, wherein the gripper grips the glass substrate using a vacuum force.

4. The system of claim 1, wherein the gripper extends across a width of the glass substrate.

5. The system of claim 1, further comprising a plurality of displacement sensors disposed on the assembly.

6. A method comprising:
attaching a probe bar to a bottom surface of a glass substrate;
transporting the glass substrate under a camera using an air table with the probe bar, wherein the air table includes an array of rail chucklets, each of the rail chucklets having apertures configured to emit gas as air bearings;
delivering driving signals to the glass substrate using the probe bar through a plurality of probe pins during the transporting of the glass substrate; and
moving the camera across a width of a top surface of the glass substrate, wherein the top surface is opposite the bottom surface.

7. The method of claim 6, further comprising inspecting the glass substrate with a camera disposed a distance from the top surface of the glass substrate during the transporting of the glass substrate.

8. The method of claim 7, wherein the probe pins are disengaged from the glass substrate after the inspecting is complete for an entirety of the glass substrate.

9. The method of claim 7, further comprising removing the probe bar from the bottom surface of the glass surface after the inspecting is complete for an entirety of the glass substrate.

10. The method of claim 7, wherein the probe pins are disengaged from the glass substrate after the inspecting is complete for a row of panels on the glass substrate.

11. The method of claim 7, further comprising removing the probe bar from the bottom surface of the glass surface after the inspecting is complete for a row of panels on the glass substrate.

12. The method of claim 6, further comprising classifying defects in the glass substrate using the data from the camera.

13. The method of claim 6, further comprising vacuum gripping the bottom surface of the glass substrate using an assembly with the probe bar during the transporting and the delivering.

14. The method of claim 13, further comprising disengaging the vacuum gripping after inspecting is complete for an entirety of the glass substrate.

15. The method of claim 13, further comprising disengaging the vacuum gripping after inspecting is complete for a row of panels on the glass substrate.
